(19) United States
(12) Patent Application Publication
(10) Pub. No.: US 2023/0360933 A1
(43) Pub. Date: Nov. 9, 2023

(54) SUBSTRATE TREATING FACILITY AND SUBSTRATE TREATING METHOD

(71) Applicant: SEMES CO., LTD., Chungcheongnam-do (KR)

(72) Inventors: Tae Shin KIM, Gyeonggi-do (KR); Ji Hoon JEONG, Gyeonggi-do (KR); Young Dae CHUNG, Incheon (KR); Jee Young LEE, Gyeonggi-do (KR); Won-Geun KIM, Gyeonggi-do (KR)

(21) Appl. No.: 17/739,377

(22) Filed: May 9, 2022

(51) Int. Cl. H01L 21/67; G02B 27/09; G02B 5/00; B23K 26/06; B23K 26/073; B23K 26/03

(52) U.S. Cl. CPC H01L 21/6708; G02B 27/0955; G02B 5/001; G02B 27/0927; B23K 26/0652; B23K 26/0734; B23K 26/034; B23K 26/0648; B23K 26/127

(57) ABSTRACT

The present invention provides a substrate treating facility, including: a process chamber including an annular beam emitting unit which emits an annular laser beam to a substrate and heats the substrate; and a laser beam generator configured to generate the laser beam emitted to the substrate through the annular beam emitting unit of the process chamber.

### TECHNICAL FIELD

The present invention relates to a substrate treating facility and a substrate treating method.

### BACKGROUND ART

In order to manufacture a semiconductor device or a liquid crystal display, various processes, such as photography, ashing, ion implantation, thin film deposition, and cleaning, are performed on a substrate. Among them, the etching process or the cleaning process is a process for removing unnecessary regions from a thin film formed on a substrate, and high selectivity for the thin film, high etch rate, and etch uniformity are required, and higher levels of etch selectivity and etch uniformity are required as semiconductor devices are highly integrated.

In general, in the etching process or cleaning process of the substrate, a chemical treatment operation, a rinse treatment operation, and a drying treatment operation are sequentially performed. In the chemical treatment operation, a chemical for etching the thin film formed on the substrate or removing foreign substances on the substrate is emitted to the substrate, and in the rinse treatment operation, a rinse solution, such as pure water, is supplied onto the substrate. As such, processing of the substrate through the fluid may be accompanied by heating of the substrate.

### SUMMARY OF THE INVENTION

The present invention has been made in an effort to provide a substrate treating facility capable of improving etching performance.

The present invention has also been made in an effort to provide a substrate treating facility capable of precisely controlling a temperature of a substrate by rapidly increasing and decreasing the temperature of the substrate.

The present invention has also been made in an effort to provide a substrate treating facility capable of effectively adjusting an optical distribution by heating a substrate by irradiating the substrate with laser beam light.

The present invention has also been made in an effort to provide a substrate treating facility capable of effectively adjusting an intensity of light by heating a substrate by irradiating the substrate with laser beam light.

present invention has also been made in an effort to provide a substrate treating facility capable of compensating for a temperature decrease that is a factor of a decrease in an etch rate (ER) for each region on a substrate.

The object of the present invention is not limited thereto, and other objects not mentioned will be clearly understood by those of ordinary skill in the art from the following description.

An exemplary embodiment of the present invention provides a substrate treating facility, including: a process chamber including an annular beam emitting unit which emits an annular laser beam to a substrate and heats the substrate; and a laser beam generator configured to generate the laser beam emitted to the substrate through the annular beam emitting unit of the process chamber.

In the exemplary embodiment, the annular beam emitting unit may include: an annular beam size adjusting module which is provided as one pair of lenses and adjusts a diameter of the annular laser beam; and a beam expanding lens which is disposed in a downstream along an optical path of the annular laser beam to diffuse the annular laser beam to the substrate.

In the exemplary embodiment, the one pair of lenses constituting the annular beam size adjusting module may be provided with axicon lens.

In the exemplary embodiment, the annular beam emitting unit may further include a moving module that enables any one of the pair of axicon lenses to relatively move with respect to the other, and adjustment of the diameter of the annular laser beam may be achieved by adjusting a spaced distance between the one pair of axicon lenses.

In the exemplary embodiment, the laser beam generator may include: a laser source unit which outputs a laser beam from energy obtained from external power; a beam shaper which converts the laser beam output from the laser source unit into a truncated Gaussian beam or a flattop beam; and a beam expander which enlarges the laser beam shaped by the beam shaper to a type of parallel light having a predetermined diameter.

In the exemplary embodiment, the process chamber may further include a front beam emitting unit which emits a front laser beam to a front surface of the substrate and heats the substrate.

In the exemplary embodiment, the annular beam emitting unit may be optically connected with the laser beam generator by a laser beam transmitting member.

In the exemplary embodiment, the laser beam transmitting member may be provided with optical fiber.

In the exemplary embodiment, the substrate treating facility may further include a controller, in which the process chamber may further include a heat detecting device which detects a temperature for each area of the substrate in real time, and the annular beam emitting unit may include: a moving module which adjusts a diameter of the annular laser beam by enabling any one of the pair of axicon lenses to relatively move with respect to the other and adjusting a spaced distance between the one pair of axicon lenses; and a beam expanding lens which is disposed in a downstream along an optical path of the annular laser beam to diffuse the annular laser beam to the substrate, and the laser beam generator may include: a laser source unit which outputs a laser beam from energy from external power; a beam shaper which converts the laser beam output from the laser source unit into a beam shape; and a beam expander which enlarges the laser beam shaped by the beam shaper to a type of parallel light with a predetermined diameter, and the controller may feedback-control one or more of a diameter of the annular laser beam by the movement of the moving module, an output of the laser source unit, the shape of the laser beam by the beam shaper, and a diameter of the laser beam shaped by the beam expander from real-time data detected by the heat detecting device.

In the exemplary embodiment, the process chamber may further include: a substrate support unit which supports the substrate and rotates the substrate; and a liquid supply unit including a chemical liquid discharge nozzle which discharges a chemical liquid to the substrate supported by the substrate support unit.

In the exemplary embodiment, the substrate support unit may include: a window member which is made of a material allowing the laser beam emitted from the annular beam emitting unit to pass through and is provided under the substrate; a chuck pin which supports a side portion of the substrate and makes the window member and the substrate be spaced apart from each other at a predetermined internal; a spin housing which is coupled with the window member and is penetrated in a vertical direction to provide a path through which the laser beam is transmitted; and a driving member which rotates the spin housing, and the annular beam emitting unit may be provided under the window member.

In the exemplary embodiment, the chemical liquid discharged from the liquid supply unit may include a liquid containing phosphoric acid.

In the exemplary embodiment, the substrate treating facility may further include a controller, in which process chamber may further include: a front beam emitting unit which emits a front laser beam to a front surface of the substrate to heat the substrate; and a heat detecting device which detects a temperature for each area of the substrate in real time, and the process chamber performs a first process of supplying the chemical liquid to the substrate, and a second process of heating the substrate with the front laser beam, and the controller may feedback-control a profile of the annular laser beam from real-time data detected by the heat detecting device.

In the exemplary embodiment, the process chamber may further include a stage which moves up and down the annular beam emitting unit so that a distance between the annular beam emitting unit and the substrate is adjustable.

In the exemplary embodiment, the front beam emitting unit may include a lens module which includes one or more lens units, and processes the front laser beam to a shape corresponding to the substrate by refracting the front laser beam, and an end of a laser beam transmitting member transmitting the front laser beam to the lens module and the lens unit may be provided so that a distance therebetween is adjustable.

In the exemplary embodiment, the laser beam transmitting member may be provided with optical fiber.

Another exemplary embodiment of the present invention provides a method of treating a substrate, the method including: a process chamber for liquid-treating a substrate in a single-wafer type; an annular beam emitting unit provided to the process chamber and configured to emit an annular laser beam to the substrate and heat the substrate; a heat detecting device provided to the process chamber and configured to detect a temperature for each area of the substrate in real time; and a laser beam generator configured to generate the laser beam emitted to the substrate through the annular beam emitting unit, and the annular beam emitting unit includes: one pair of axicon lenses; a moving module which adjusts a diameter of the annular laser beam by enabling any one of the pair of axicon lenses to relatively move with respect to the other and adjusting a spaced distance between the one pair of axicon lenses; a beam expanding lens which is disposed in a downstream along an optical path of the annular laser beam to diffuse the annular laser beam to the substrate, and a laser source unit which outputs a laser beam from energy from external power; a beam shaper which converts the laser beam output from the laser source unit into a beam shape; and a beam expander which enlarges the laser beam shaped by the beam shaper to a type of parallel light with a predetermined diameter, and the controller feedback-controls one or more of the diameter of the annular laser beam by the movement of the moving module, an output of the laser source unit, the shape of the laser beam by the beam shaper, and a diameter of the laser beam shaped by the beam expander from real-time data detected by the heat detecting device.

In the exemplary embodiment, the process chamber may further include a front beam emitting unit which emits a front laser beam to a front surface of the substrate and heats the substrate, and the process chamber may perform a first process of supplying a chemical liquid to the substrate, and a second process of heating the substrate with the front laser beam, and a profile of the annular laser beam may be feedback-controlled from real-time data detected by the heat detecting device to correct heating of the substrate by the front laser beam.

In the exemplary embodiment, the chemical liquid may be a liquid containing phosphoric acid.

Another exemplary embodiment of the present invention provides a substrate treating facility, including: a process chamber for liquid-treating a substrate in a single-wafer type; a substrate support unit which is provided to the process chamber to support the substrate and rotate the substrate; a liquid supply unit including a chemical liquid discharge nozzle which discharges a chemical liquid containing phosphoric acid to the substrate supported by the substrate support unit; an annular beam emitting unit which is provided to the process chamber to emit an annular laser beam to the substrate and heat the substrate; a front beam emitting unit configured to emit a front laser beam to a front surface of the substrate and heat the substrate; a heat detecting device provided to the process chamber to detect a temperature for each area of the substrate in real time; a laser beam generator configured to generate the laser beam emitted to the substrate through the annular beam emitting unit; and a control unit, in which the annular beam emitting unit includes: one pair of axicon lenses; a moving module which adjusts a diameter of the annular laser beam by enabling any one of the pair of axicon lenses to relatively move with respect to the other and adjusting a spaced distance between the one pair of axicon lenses; and a beam expanding lens which is disposed in a downstream along an optical path of the annular laser beam to diffuse the annular laser beam to the substrate, and the laser beam generator include: a laser source unit which outputs a laser beam from energy from external power; a beam shaper which converts the laser beam output from the laser source unit into a beam shape; and a beam expander which enlarges the laser beam shaped by the beam shaper to a type of parallel light with a predetermined diameter, and the controller feedback-controls one or more of the diameter of the annular laser beam by the movement of the moving module, an output of the laser source unit, the shape of the laser beam by the beam shaper, and a diameter of the laser beam shaped by the beam expander from real-time data detected by the heat detecting device.

According to the exemplary embodiment of the present invention, etch performance may be improved.

According to the exemplary embodiment of the present invention, the temperature of the substrate is rapidly increased and decreased, so that it is possible to precisely control the temperature of the substrate.

According to the exemplary embodiment of the present invention, it is possible to effectively adjust an optical distribution by heating the substrate by irradiating the substrate with laser beam light.

According to the exemplary embodiment of the present invention, it is possible to effectively adjust intensity of light by heating the substrate by irradiating the substrate with laser beam light.

According to the exemplary embodiment of the present invention, it is possible to compensate for a temperature decrease that is a factor of a decrease in an etch rate for each region on the substrate.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a top plan view illustrating a substrate treating facility 1 according to an exemplary embodiment of the present invention.

FIG. 2 is a cross-sectional view illustrating a substrate treating apparatus 300 according to a first exemplary embodiment provided to a process chamber 260 of FIG. 1.

FIG. 3 is a schematic diagram illustrating a laser beam generator 500 providing the process chamber 260 of FIG. 1 with a laser beam.

FIG. 4 is a side view of a front beam emitting unit 400-1 according to the first exemplary embodiment.

FIG. 5 is a schematic cross-sectional view illustrating a first use state of the front beam emitting unit 400-1 according to the first exemplary embodiment of FIG. 4.

FIG. 6 is a schematic cross-sectional view illustrating a second use state of the front beam emitting unit 400-1 according to the first exemplary embodiment of FIG. 4.

FIG. 7 is a diagram illustrating a change in intensity of the laser beam according to an adjustment of a distance between an end of a laser beam transmitting member 443 and a lens part 442b.

FIG. 8 is a side view of a front beam emitting unit 400-2 according to a second exemplary embodiment.

FIG. 9 is a diagram illustrating a change in intensity of a laser beam according to an adjustment of a distance between the front beam emitting unit 400 and a target (for example, a wafer).

FIG. 10 is a cross-sectional view illustrating a substrate treating apparatus according to a second exemplary embodiment provided to the process chamber 260 of FIG. 1.

FIG. 11 is a schematic cross-sectional view of an annular beam emitting unit 700 according to an exemplary embodiment of the present invention.

FIG. 12 is a configuration diagram illustrating a feedback control method in heating a substrate W according to the exemplary embodiment of the present invention.

FIG. 13 is a diagram illustrating energy distribution of the laser beam incident on the annular beam emitting unit 700.

FIG. 14 is a diagram representing a comparison of diameters of the annular beams adjusted by an annular beam size adjusting module 710 when the laser beam of FIG. 13 is incident on the annular beam emitting unit 700.

FIG. 15 is a diagram representing a comparison of beam profiles adjusted by the annular beam size adjusting module 710 according to a shape and a size of the laser beam incident on the annular beam emitting unit 700.

FIG. 16 is a diagram schematically illustrating a first application exemplary embodiment of the present invention.

FIG. 17 is a diagram schematically illustrating a second application exemplary embodiment of the present invention.

FIG. 18 is a diagram schematically illustrating a third application exemplary embodiment of the present invention.

FIG. 19 is a diagram schematically illustrating a fourth application exemplary embodiment of the present invention.

FIG. 20 is a diagram schematically illustrating a fifth application exemplary embodiment of the present invention.

FIG. 21 is a diagram schematically illustrating a combined beam in a shape in which the laser beams illustrate an exemplary embodiment of the present invention.

### DETAILED DESCRIPTION

Hereinafter, an exemplary embodiment of the present invention will be described more fully hereinafter with reference to the accompanying drawings, in which exemplary embodiments of the invention are shown. However, the present invention can be variously implemented and is not limited to the following embodiments. In addition, in describing an exemplary embodiment of the present invention in detail, if it is determined that a detailed description of a related well-known function or configuration may unnecessarily obscure the gist of the present invention, the detailed description thereof will be omitted. In addition, the same reference numerals are used throughout the drawings for parts having similar functions and actions.

In addition, unless explicitly described to the contrary, the word “comprise” and variations such as “comprises” or “comprising” will be understood to imply the inclusion of stated elements but not the exclusion of any other elements. It will be appreciated that terms “including” and “having” are intended to designate the existence of characteristics, numbers, steps, operations, constituent elements, and components described in the specification or a combination thereof, and do not exclude a possibility of the existence or addition of one or more other characteristics, numbers, steps, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

An expression, “and/or” includes each of the mentioned items and all of the combinations including one or more of the items. Further, in the present specification, “connected” means not only when member A and member B are directly connected, but also when member A and member B are indirectly connected by interposing member C between member A and member B.

The exemplary embodiment of the present invention may be modified in various forms, and the scope of the present invention should not be construed as being limited to the following exemplary embodiments. The present exemplary embodiment is provided to more completely explain the present invention to those skilled in the art. Therefore, the shapes of elements in the drawings are exaggerated to emphasize clearer descriptions.

In the present exemplary embodiment, a process of etching a substrate by using a treatment liquid will be described as an example. However, the present exemplary embodiment is not limited to the etching process, and is variously applicable to substrate treating processes using liquids, such as a cleaning process, an ashing process, and a developing process.

Herein, a substrate is a comprehensive concept that includes all substrates used for manufacturing semiconductor devices, flat panel displays (FPDs), and other products with circuit patterns formed on thin films. Examples of the substrate W include a silicon wafer, a glass substrate, and an organic substrate.

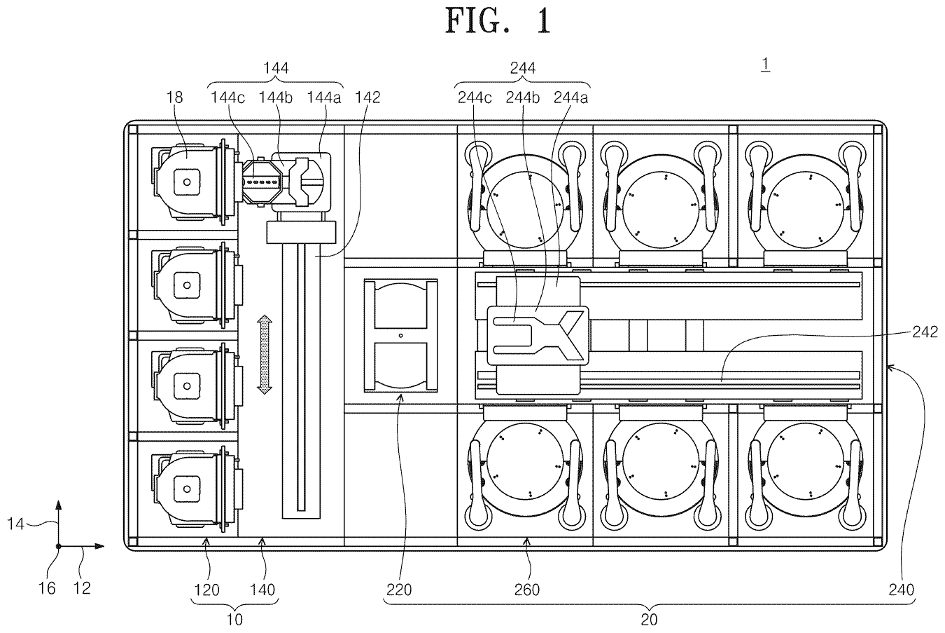

Hereinafter, an example of the present invention will be described in detail with reference to FIGS. 1 to 20.

FIG. 1 is a top plan view illustrating a substrate treating facility 1 according to an exemplary embodiment of the present invention. Referring to FIG. 1, the substrate treating facility 1 includes an index module 10 and a process processing module 20. The index module 10 includes a load port 120 and a transfer frame 140. The load port 120, the transfer frame 140, and the process processing module 20 may be sequentially arranged in series.

Hereinafter, a direction in which the load port 120, the transfer frame 140, and the process processing module 20 are arranged is called a first direction 12, a direction perpendicular to the first direction 12 when viewed from the top is called a second direction 14, and a direction perpendicular to a plane including the first direction 12 and the second direction 14 is called a third direction 16.

A carrier 18 in which a substrate W is accommodated is seated on the load port 120. A plurality of load ports 120 is provided, and is disposed in series in the second direction 14. The number of load ports 120 may be increased or decreased according to process efficiency of the process processing module 20 and a condition of foot print, and the like. A plurality of slots (not illustrated) for accommodating the plurality of substrates W in a state where the substrates W are arranged horizontally with respect to the ground may be formed in the carrier 18. As the carrier 18, a Front Opening Unified Pod (FOUP) may be used.

The process processing module 20 includes a buffer unit 220, a transfer chamber 240, and a process chamber 260.

The transfer chamber 240 is disposed so that a longitudinal direction thereof is parallel to the first direction 12. The plurality of process chambers 260 may be disposed at one side or both sides of the transfer chamber 240. The plurality of process chambers 260 may be provided to be symmetric based on the transfer chamber 240 at one side and the other side of the transfer chamber 240. Some of the process chambers 260 are disposed in the longitudinal direction of the transfer chamber 240. Further, some of the process chambers 260 are disposed to be stacked with each other. That is, the plurality of process chambers 260 may be disposed in an array of A×B at one side of the transfer chamber 240. Herein, A is the number of process chambers 260 provided in series in the first direction 12, and B is the number of process chambers 260 provided in series in the third direction 16. When four or six process chambers 260 are provided at one side of the transfer chamber 240, the plurality of process chambers 260 may be disposed in an array of 2×2 or 3×2. The number of process chambers 260 may be increased or decreased. Unlike the above, the process chambers 260 may be provided only to one side of the transfer chamber 240. Further, the process chambers 260 may be provided in a single layer at one side and both sides of the transfer chamber 240.

The buffer unit 220 is disposed between the transfer frame 140 and the transfer chamber 240. The buffer unit 220 provides a space in which the substrate W stays before the substrate W is transferred between the transfer chamber 240 and the transfer frame 140. Slots (not illustrated) on which the substrate W is placed is provided inside the buffer unit 220. The plurality of slots (not illustrated) is provided so as to be spaced apart from each other in the third direction 16. A surface of the buffer unit 220 facing the transfer frame 140 and a surface of the buffer unit 220 facing the transfer chamber 240 are opened.

The transfer frame 140 transfers the substrate W between the carrier 130 seated on the load port 120 and the buffer unit 220. An index rail 142 and an index robot 144 are provided to the transfer frame 140. The index rail 142 is provided so that a longitudinal direction thereof is parallel to the second direction 14. The index robot 144 is installed on the index rail 142, and linearly moves in the second direction 14 along the index rail 142. The index robot 144 includes a base 144a, a body 144b, and an index arm 144c. The base 144a is installed to be movable along the index rail 142. The body 144b is coupled to the base 144a. The body 144b is provided to be movable in the third direction 16 on the base 144a. Further, the body 144b is provided to be rotatable on the base 144a. The index arm 144c is coupled to the body 144b and is provided to be movable forwardly and backwardly with respect to the body 144b. A plurality of index arms 144c is provided to be individually driven. The index arms 144c are disposed to be stacked in the state of being spaced apart from each other in the third direction 16. A part of the index arms 144c may be used when the substrate W is transferred from the process processing module 20 to the carrier 18, and another part of the plurality of index arms 144c may be used when the substrate W is transferred from the carrier 18 to the process processing module 20. This may prevent the particles generated from the substrate W before the process processing from being attached to the substrate W after the process processing in the process in which the index robot 144 loads and unloads the substrate W.

The transfer chamber 240 transfers the substrate W between the buffer unit 220 and the process chamber 260, and between the process chambers 260. A guide rail 242 and a main robot 244 are provided to the transfer chamber 240. The guide rail 242 is disposed so that a longitudinal direction thereof is parallel to the first direction 12. The main robot 244 is installed on the guide rail 242, and linearly moves on the guide rail 242 in the first direction 12. The main robot 244 includes a base 244a, a body 244b, and a main arm 244c. The base 244a is installed to be movable along the guide rail 242. The body 244b is coupled to the base 244a. The body 244b is provided to be movable in the third direction 16 on the base 244a. Further, the body 244b is provided to be rotatable on the base 244a. The main arm 244c is coupled to the body 244b and provided to be movable forwardly and backwardly with respect to the body 244b. A plurality of main arms 244c is provided to be individually driven. The main arms 244 are disposed to be stacked in the state of being spaced apart from each other in the third direction 16.

A substrate treating apparatus 300 performing a liquid treatment process on the substrate W is provided to the process chamber 260. The substrate treating apparatus 300 may have a different structure depending on the type of liquid treatment process to be performed. Contrary to this, the substrate treating apparatus 300 within each process chamber 260 may have the same structure. Optionally, the plurality of process chambers 260 is divided into a plurality of groups, and the substrate treating apparatuses 300 within the process chambers 260 belong to the same group may have the same structure, and the substrate treating apparatuses 300 within the process chambers 260 belong to the different groups may have the different structures.

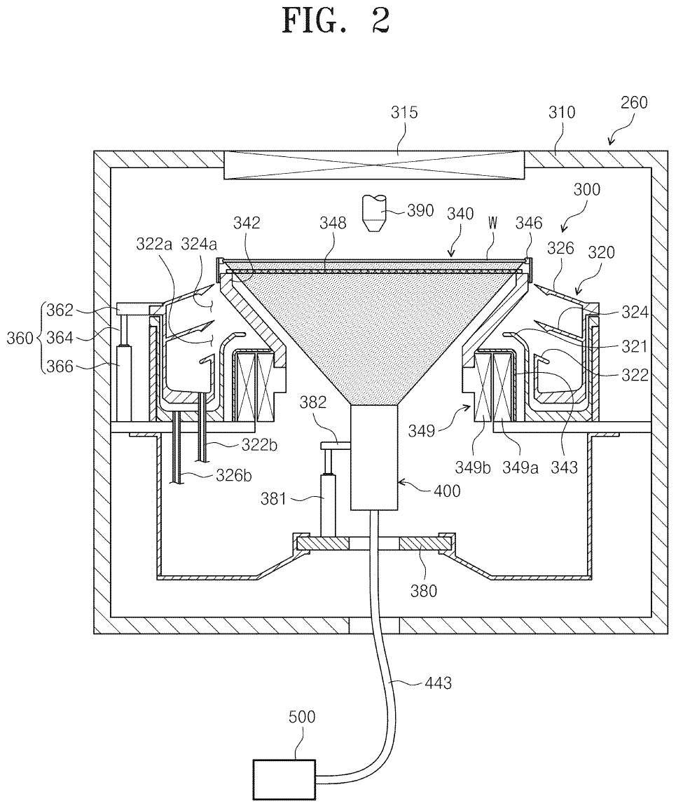

FIG. 2 is a cross-sectional view illustrating the substrate treating apparatus 300 according to a first exemplary embodiment provided to a process chamber 260 of FIG. 1. Referring to FIG. 2, the substrate treating apparatus 300 includes a treating vessel 320, a substrate support unit 340, a lift unit 360, a liquid supply unit 390, and a controller (not illustrated).

The treating vessel 320 has a cylindrical shape with an open top. The treating vessel 320 includes a first collection container 321 and a second collection container 322. The collection containers 321 and 322 collect different treatment liquids among the treatment liquids used for the process. The first collection container 321 is provided in an annular ring shape surrounding the substrate support unit 340. The second collection container 322 is provided in an annular ring shape surrounding the substrate support unit 340. In the exemplary embodiment, the first collection container 321 is provided in an annular ring shape surrounding the second collection container 322. The second collection container 322 may be provided while being inserted into the first collection container 321. A height of the second collection container 322 may be larger than a height of the first collection container 321. The second collection container 322 may include a first guard part 326 and a second guard part 324. The first guard part 326 may be provided to the topmost portion of the second collection container 322. The first guard part 326 is formed while being extended toward the substrate support unit 340, and the first guard part 326 may be formed to be inclined upward toward the substrate support unit 340. In the second collection container 322, the second guard part 324 may be provided to a position spaced apart from the first guard part 326 in the down direction. The second guard part 324 is formed while being extended toward the substrate support unit 340, and the second guard part 326 may be formed to be inclined upward toward the substrate support unit 340. A first inlet 324a through which a treatment liquid is introduced is provided between the first guard part 326 and the second guard part 324. A second inlet 322a is provided at a lower portion of the second guard part 324. The first inlet 324a and the second inlet 322a may be located at different heights. A hole (not illustrated) is formed in the second guard part 324, so that the treatment liquid introduced through the first inlet 324a flows to a second collection line 322b provided in the lower portion of the second collection container 322. The hole (not illustrated) of the second guard part 324 may be formed at a position with the lowest height in the second guard part 324. The treatment liquid collected to the first collection container 321 is configured to flow to a first collection line 321b connected to a bottom surface of the first collection container 321. The treatment liquids introduced into the collection containers 321 and 322 may be provided to an external treatment liquid recycling system (not illustrated) through the collection lines 321b and 322b, respectively, to be re-used.

The lift unit 360 linearly moves the treating vessel 320 in the vertical direction. For example, the lift unit 360 is coupled to the second collection container 322 of the treating vessel 320 to move the second collection container 322 in the vertical direction, so that a relative height of the treating vessel 320 with respect to the substrate support unit 340 may be changed. The lift unit 360 includes a bracket 362, a movement shaft 364, and a driver 366. The bracket 362 is fixedly installed to an external wall of the treating vessel 320, and the movement shaft 364 moved in the vertical direction by the driver 366 is fixedly coupled to the bracket 362. The second collection container 322 of the treating vessel 320 moves down so that an upper portion of the substrate support unit 340 protrudes above the treating vessel 320 when the substrate W is loaded into the substrate support unit 340 or is unloaded from the substrate support unit 340. Further, when the process proceeds, the height of the treating vessel 320 is adjusted so that the treatment liquid is introduced into the predetermined collection container 321 and 322 depending on the type of the treatment liquid supplied to the substrate W. Optionally, the lift unit 360 may also move the substrate support unit 340 in the vertical direction instead of the treating vessel 320. Optionally, the lift unit 360 may also move the entire treatment vessel 320 to be movable up and down in the vertical direction. The lift unit 360 is provided to adjust the relative height of the treating vessel 320 and the substrate support unit 340, and if the treating vessel 320 and the substrate support unit 340 have a configuration capable of adjusting the relative heights, the exemplary embodiments of the processing vessel 320 and the lift unit 360 may be provided in various structures and methods depending on the design.

The substrate support unit 340 supports the substrate W and rotates the substrate W during the process progress.

The substrate support unit 340 includes a window member 348, a spin housing 342, a chuck pin 346, and a driving member 349.

The window member 348 is located under the substrate W. The window member 348 may be provided in a shape substantially corresponding to the substrate W. For example, when the substrate W is a circular wafer, the window member 348 may be provided in a generally circular shape. The window member 348 may have the same diameter as that of the substrate W, have a smaller diameter than that of the substrate W, or have a larger diameter than that of the substrate W. The window member 348 is a configuration that allows the laser beam to pass through and reach the substrate W, and protects the configuration of the substrate support unit 340 from a chemical liquid, and may be provided in various sizes and shapes depending on the design. The support member 113 may be formed of a larger diameter than the diameter of the wafer.

The window member 348 may be made of a material having high light transmittance. Therefore, the laser beam emitted from the front beam emitting unit 400 may pass through the window member 348. The window member 348 may be made of a material having excellent corrosion resistance so as not to react with the chemical liquid. For this purpose, the material of the window member 348 may be, for example, quartz, glass, or sapphire.

The spin housing 342 may be provided to the bottom surface of the window member 348. The spin housing 342 supports an edge of the window member 348. The spin housing 342 provides an empty space penetrated in the vertical direction therein. The empty space formed by the spin housing 342 may be formed to have an inner diameter increasing toward the window member 348 from the portion adjacent to the front beam emitting unit 400. The spin housing 342 may have a cylindrical shape in which an inner diameter increases from the bottom to the top. The laser beam generated by the front beam emitting unit 400, which will be described later, may be emitted to the substrate W without being interfered by the spin housing 342 by the inner empty space. A connection portion between the spin housing 342 and the window member 348 may have a sealed structure so that the chemical liquid supplied to the substrate W does not penetrate in the direction of the front beam emitting unit 400.

The driving member 349 may be coupled to the spin housing 342 to rotate the spin housing 342. The driving member 349 may be any one capable of rotating the spin housing 342. For example, the driving member 349 may be provided in a hollow motor. According to the exemplary embodiment, the driving member 349 includes a stator 349a and a rotator 349b. The stator 349a is fixed at one position, and the rotator 349b is coupled to the spin housing 342. According to the illustrated exemplary embodiment, the hollow motor in which the rotator 349b is provided to an inner diameter and the stator 349a is provided to an outer diameter is illustrated. According to the illustrated example, the lower portion of the spin housing 342 is coupled with the rotator 349b to be rotated by the rotation of the rotator 349b. When the hollow motor is used as the driving member 349, the narrower the bottom of the spin housing 342 is provided, the smaller the hollow of the hollow motor may be selected, and thus the manufacturing cost may be reduced. According to the exemplary embodiment, the stator 349a of the driving member 349 may be provided while being fixed coupled to a support surface by which the treating vessel 320 is supported. According to the exemplary embodiment, a cover member 343 protecting the driving member 349 from the chemical liquid may be further included.

The liquid supply unit 349 is the configuration for discharging the chemical liquid to the substrate W above the substrate W, and may include one or more chemical liquid discharge nozzles. The liquid supply unit 390 may pump and transport the chemical liquid stored in a storage tank (not illustrated) to discharge the chemical liquid to the substrate W through the chemical liquid discharge nozzle. The liquid supply unit 390 may include a driving unit to be movable between a process position directly above the center of the substrate W and a standby position outside the substrate W.

The chemical liquid supplied from the liquid supply unit 390 to the substrate W may be various depending on the substrate treatment process. When the substrate treatment process is a silicon nitride film etching process, the chemical liquid may be a chemical liquid including phosphoric acid (H₃PO₄). The liquid supply unit 390 may further include a deionized water (DIW) supply nozzle for rinsing the surface of the substrate after the etching process, and an isopropyl alcohol (IPA) discharge nozzle and a nitrogen (N₂) discharge nozzle for performing a drying process after rinsing. Although not illustrated, the liquid supply unit 390 may include a nozzle moving member (not illustrated) which is capable of supporting the chemical liquid discharge nozzle and moving the chemical liquid discharge nozzle. The nozzle moving member (not illustrated) may include a support shaft (not illustrated), an arm (not illustrated), and a driver (not illustrated). The support shaft (not illustrated) is located at one side of the treating vessel 320. The support shaft (not illustrated) includes a rod shape of which a longitudinal direction faces the third direction. The support shaft (not illustrated) is provided to be rotatable by the driver (not illustrated). The arm (not illustrated) is coupled to an upper end of the support shaft (not illustrated). The arm (not illustrated) may be extended vertically from the support shaft (not illustrated). The chemical liquid discharge nozzle is fixedly coupled to the distal end of the arm (not illustrated). According to the rotation of the support shaft (not illustrated), the chemical liquid discharge nozzle is capable of swing together with the arm (not illustrated). The chemical liquid discharge nozzle may be swing-moved to move to the process position and the standby position. Optionally, the support shaft (not illustrated) may be provided to be movable up and down. Further, the arm (not illustrated) may be provided to be movable forward and backward toward the longitudinal direction thereof.

The front beam emitting unit 400 is the configuration for emitting the laser beam to the substrate W. The front beam emitting unit 400 may be positioned lower than the window member 348 in the substrate support unit 340. The front beam emitting unit 400 may emit the laser beam toward the substrate W located on the substrate support unit 340. The laser beam emitted from the front beam emitting unit 400 may pass through the window member 348 of the substrate support unit 340 to be emitted to the substrate W. Accordingly, the substrate W may be heated to a set temperature.

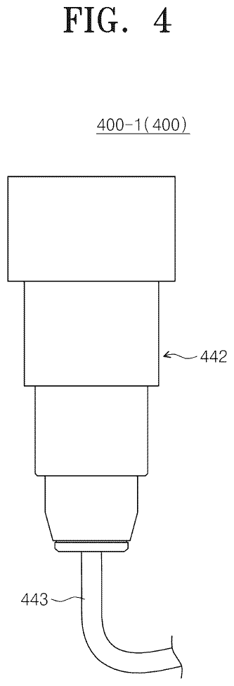

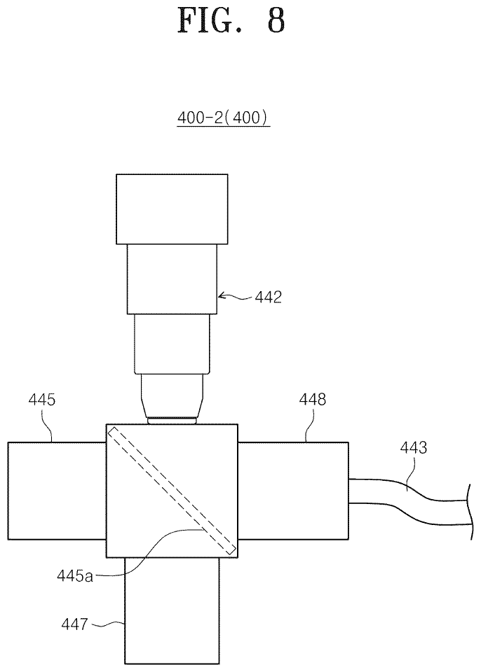

The front beam emitting unit 400 may be configured to uniformly emit the laser beam to the front surface of the substrate W. The front beam emitting unit 400 is sufficient if the front beam emitting unit 400 uniformly emits the laser beam to the front surface of the substrate W, but a front beam emitting unit 400-1 according to a first exemplary embodiment will be described with reference to FIGS. 4 to 6 and a front beam emitting unit 400-2 according to a second exemplary embodiment will be described with reference to FIG. 8.

The laser beam generator 500 may generate a laser beam. The laser beam generator 500 may generate a laser beam of a wavelength that the substrate W may easily absorb. According to the exemplary embodiment, the laser beam generator 500 may be provided as a high-power device of 4 kW to 5 kW.

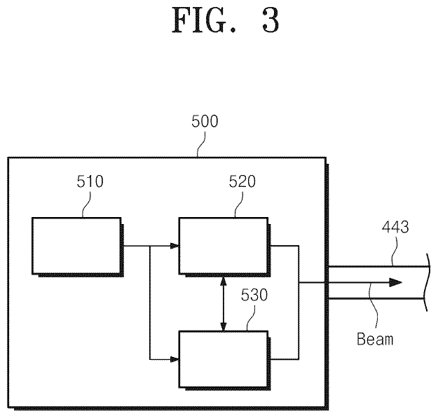

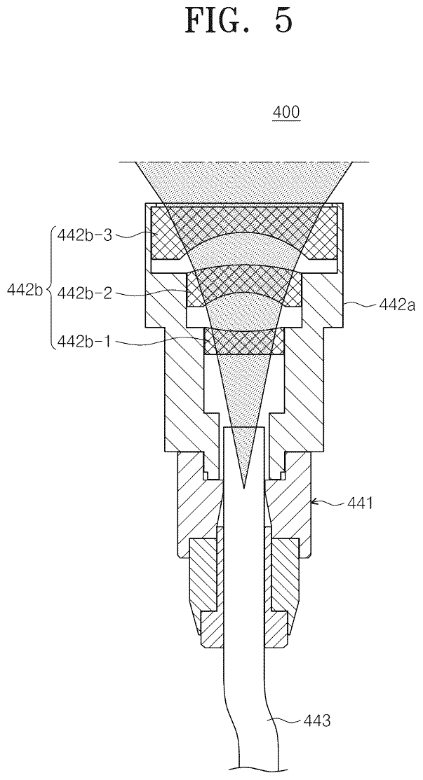

FIG. 3 is a schematic diagram illustrating the laser beam generator 500 providing the process chamber 260 of FIG. 1 with a laser beam. Referring to FIG. 3, the laser beam generator 500 may include a laser source unit 510, a beam shaper 520, and a beam expander 530. The laser source unit 510 outputs a laser beam from energy obtained from power. The beam shaper 520 converts a profile of the laser beam output from the laser source unit 510. For example, the beam shaper 520 shapes the input laser beam to a set beam shape. In the exemplary embodiment, the laser beam in the form of a Gaussian beam may be input to the beam shaper 520 and converted into a parallel flattop beam or a truncated Gaussian beam. The beam expander 530 serves to expand the laser beam in the form of parallel light having a predetermined diameter. For example, the beam expander 530 may be formed of a plurality of lens to change a diameter of the laser beam. The beam generated in the laser source unit 510 may be output while passing through the beam shaper 520 and/or the beam expander 530. For example, the beam generated in the laser source unit 510 may pass through the beam shaper 520 and/or the beam expander 530, or pass through only the beam shaper 520 or pass through only the beam expander 530. Further, according to one example, when the annular beam emitting unit 700 receives the annular laser beam generated from the laser beam generator 500, the annular beam emitting unit 700 does not need to shape the laser beam into an annular shape, so that the annular beam size adjusting module 710 may be provided in a manner different from the above-described example for adjusting the diameter of the annular laser beam. The front beam emitting unit 400-1 according to the first exemplary embodiment will be described with reference to FIGS. 4 to 6. FIG. 4 is a side view of the front beam emitting unit 400-1 according to the first exemplary embodiment. Referring to FIG. 4, the front beam emitting unit 400-1 may include a lens module 442. The front beam emitting unit 400-1 may receive the laser beam from the laser beam transmitting member 443. FIG. 5 is a schematic cross-sectional view illustrating a first use state of the front beam emitting unit 400-1 according to the first exemplary embodiment of FIG. 4. Referring further to FIG. 5, the lens module 442 includes a lens part 442b and a barrel part 442a supporting and accommodating the lens part 442b. The lens part 442b may be configured of a combination of a plurality of lens. For example, the lens part 442b may include a concave lens or a convex lens. For example, the lens part 442b may include a first lens 442b-1, a second lens 442b-2, and a third lens 442b-e. The first lens 442b-1 may have a concave upper surface to emit a laser beam. The second lens 442b-b may have a convex upper surface and a concave lower surface to emit a laser beam. The third lens 442b-3 may have a convex lower surface to emit a laser beam. Although the lens part 442b is configured by the combination of three lenses in the drawing, this is for convenience of explanation, and the number and types of lenses constituting the lens part 442b may vary according to the design of the substrate treating apparatus 300.

The laser beam transmitting member 443 is the configuration of delivering the laser beam generated in the laser beam generator 500 to the lens module 442. For example, the laser beam transmitting member 443 may be an optical fiber. The laser beam transmitting member 443 may have an end coupled to a fastening member 441 to be coupled to the lens module 442 through the fastening member 441. The fastening member 441 is provided so as to adjust the distance between the end of the laser beam transmitting member 443 and the lens part 442b.

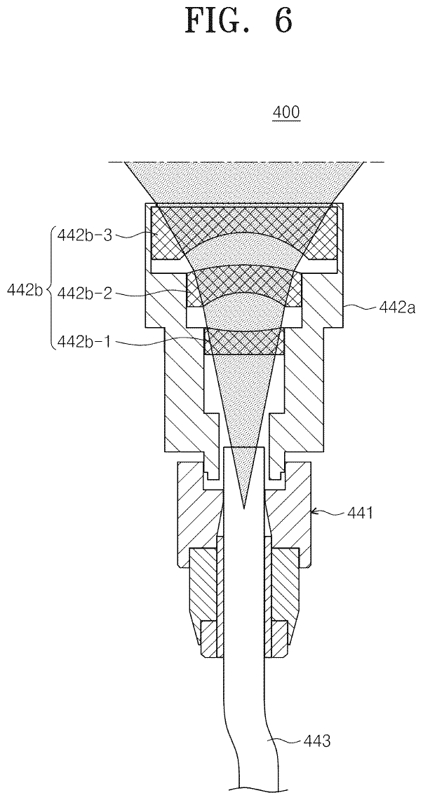

FIG. 6 is a schematic cross-sectional view illustrating a second use state of the front beam emitting unit 400-1 according to the first exemplary embodiment of FIG. 4. Referring to FIG. 6, the distance between the end of the laser beam transmitting member 443 and the lens part 442b is provided to be longer compared to the first use state of FIG. 5. According to the second use state of FIG. 6, the laser beam is distributed more widely than in the first use state of FIG. 5, and an intensity of the laser beam may be adjusted.

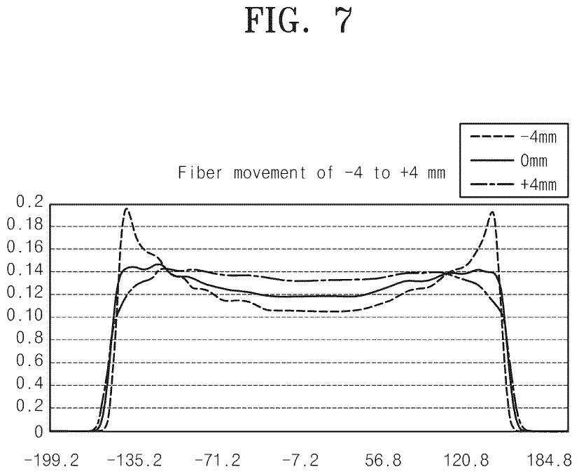

FIG. 7 is a diagram illustrating a change in intensity of the laser beam according to an adjustment of a distance between the end of the laser beam transmitting member 443 and the lens part 442b. The Y-axis (vertical axis) represents the magnitude of the intensity, and the X-axis (horizontal axis) represents the position of the laser beam with respect to the 300 mm wafer. As the end of the laser beam transmitting member 443 moves and approaches the lens part 442b, the intensity of the edge region of the substrate increases and the intensity of the central region of the substrate decreases. As an experimental example, it can be seen that in a graph illustrated with −4 mm in which the front beam emitting unit 400 and the target (for example, a wafer) are close by 4 mm, the intensity of the substrate edge region is large and the intensity of the substrate center region is small, compared to a graph illustrated with +4 mm in which the front beam emitting unit and the target are far away by 4 mm.

Although not illustrated as the exemplary embodiment, the lens part 442b is provided so that the relative distance between the lenses constituting the lens part 442b is changeable, the irradiation area and the intensity of each area may be adjusted.

The front beam emitting unit 400-2 according to the second exemplary embodiment will be described with reference to FIG. 8. Referring to FIG. 8, the front beam emitting unit 400-2 may selectively include a reflecting unit 445, a photographing unit 446, a detecting unit 447, and a collimator 448. The reflecting unit 445 may reflect a part of the laser beam which has been generated in the laser beam generator 500 and transmitted through the laser beam transmitting member 443 in the direction of the lens module 442 and allow the remaining part of the laser beam to pass through. To this end, the reflecting unit 445 may include a reflective mirror 145a installed at an angle of 45°.

The photographing unit 446 may be coupled to the reflecting unit 445, and may photograph the laser beam passing through the reflecting unit 445 and convert the photographed laser beam to image data. The photographing unit 446 may inspect whether the designed laser beam is output from the laser beam generator 500 and whether the designed laser beam is transmitted through the laser beam transmitting member 443 by analyzing the image data.

The detecting unit 447 may be coupled to the reflecting unit 445, and detect the intensity of the laser beam incident on the reflecting unit 445. The detecting unit 447 may be, for example, a photo detector. When the intensity of the laser beam is excessively large, the substrate W may be rapidly heated. Further, when the intensity of the laser beam is excessively low, it may take a long time until the substrate W is heated. The detecting unit 447 may determine whether the intensity of the laser beam has an appropriate value.

In the above, it has been described that the front beam emitting unit 400 is disposed below the substrate W to emit the laser beam to the back surface of the substrate W, but the present invention is not limited thereto. The laser beam emitting unit may be disposed above the substrate W and configured to emit the laser beam onto the upper surface of the substrate W.

Referring back to FIG. 2, the front beam emitting unit 400 may be provided while being coupled to an X, Y, Z stage 380. The X, Y, Z stage 380 may include a coupling part 382 which is connected with a lift driving unit 381 and is coupled with the front beam emitting unit 400. The position of the front beam emitting unit 400 with respect to the substrate W may be adjusted through the X, Y, Z stage 380. Further, the intensity of the laser beam may also be adjusted by adjusting the distance between the front beam emitting unit 400 and the substrate W through the lift driving unit 381.

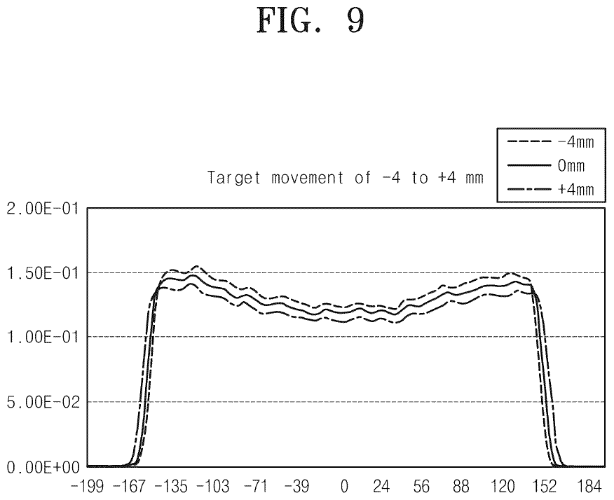

FIG. 9 is a diagram illustrating a change in intensity of a laser beam according to an adjustment of a distance between the front beam emitting unit 400 and a target (for example, a wafer). The Y-axis (vertical axis) represents the magnitude of the intensity, and the X-axis (horizontal axis) represents the position of the laser beam with respect to the 300 mm wafer. As the end of the laser beam transmitting member 443 moves and approaches the lens part 442b, the intensity increases and the irradiation area becomes narrower. As an experimental example, it can be seen that in a graph illustrated with −4 mm in which the front beam emitting unit 400 and the target (for example, a wafer) are close by 4 mm, the intensity is large and the irradiation area is narrow, compared to a graph illustrated with +4 mm in which the front beam emitting unit and the target (for example, the wafer) are far away by 4 mm. In the meantime, according to the exemplary embodiment, the laser beam generator 500 may receive a signal of a pulse generator and generate a laser beam in a form of a pulse. In this case, the pulse form may be the form in which the laser beam is on/off, or may also be the form in which the intensity of the laser beam is periodically repeated with a first intensity and a second intensity.

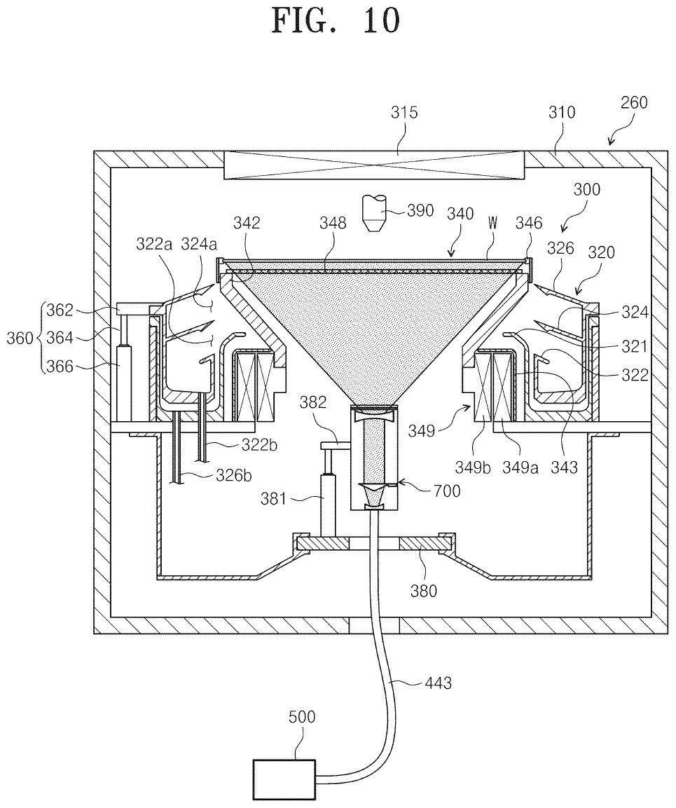

FIG. 10 is a cross-sectional view illustrating a substrate treating apparatus 1300 according to a second exemplary embodiment provided to the process chamber 260 of FIG. 1. Referring to FIG. 10, the substrate treating apparatus 1300 will be described, and the description will be focused on a configuration different from the configuration described in FIG. 2, and the same configuration will be replaced with the description of FIG. 2 by providing the same reference numerals. The substrate treating apparatus 1300 according to the second exemplary embodiment may include an annular beam emitting unit 700, not the front beam emitting unit 400, unlike the first exemplary embodiment of FIG. 2.

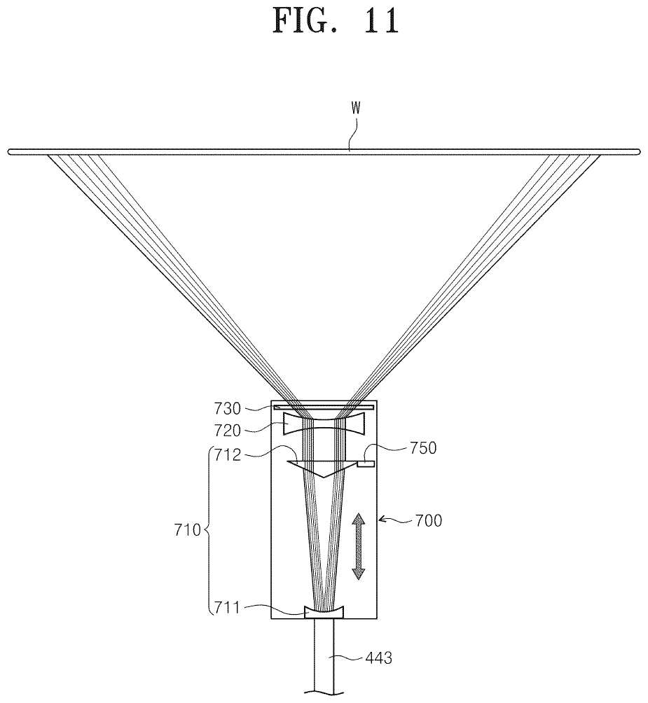

FIG. 11 is a schematic cross-sectional view of the annular beam emitting unit 700 according to an exemplary embodiment of the present invention. The annular beam emitting unit 700 will be described in more detail with further reference to FIG. 11. The annular beam emitting unit 700 according to the exemplary embodiment may include an annular beam size adjusting module 710, a beam expansion lens 720, and a window member 730 inside a housing. The annular beam size adjusting module 710 may be provided with one pair of axicon lenses. A first axicon lens may be formed such that the annular shape increases as the laser beam passes through the first axicon lens 711 and travels while shaping the laser beam in an annular shape. A second axicon lens 712 may convert the annular laser beam into parallel light.

In the exemplary embodiment, the second axicon lens 712 may be coupled to a moving module 750 and provided to be movable. A diameter of the annular laser beam may be changed by the movement of the second axicon lens 712.

The beam expansion lens 720 expands the annular laser beam which has passed through the second axicon lens 712. The annular laser beam which has passed through the beam expansion lens 710 reaches the substrate W as the annular shape increases as the annular laser beam travels.

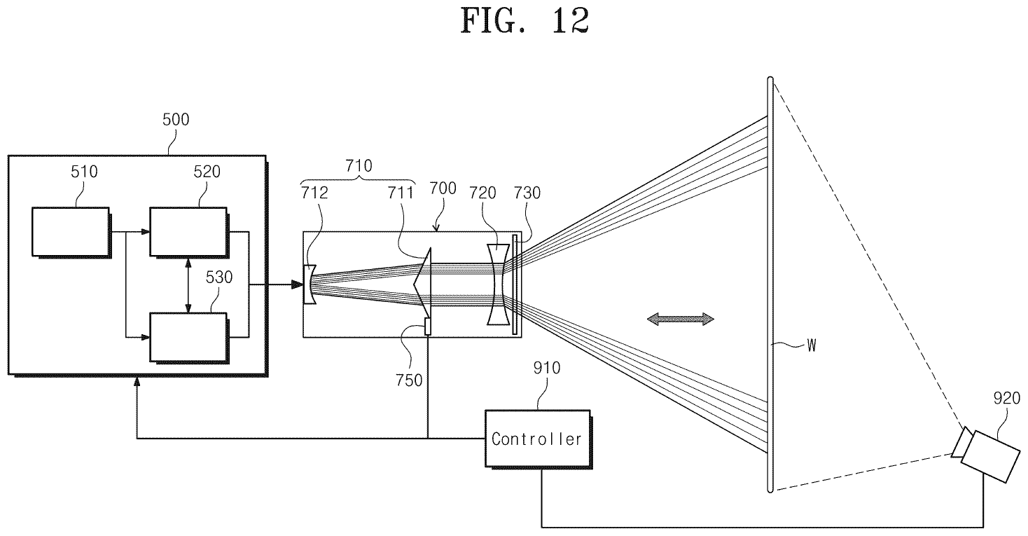

The window member 730 allows the laser beam to pass through and protects the lens provided to the annular beam emitting unit 700 from an external environment. FIG. 12 is a configuration diagram illustrating a feedback control method in heating the substrate W according to the exemplary embodiment of the present invention. According to the exemplary embodiment, a phosphoric acid puddle (not shown) is formed on the upper surface of the substrate W, and the substrate W is heated by emitting a laser beam. The heating of the substrate W may be detected by a heat detecting device 920 in real time. According to the exemplary embodiment, the heat detecting device 920 may be provided as a non-contact temperature sensor, such as a thermal imager or a pyrometer.

A temperature of the substrate W detected by the heat detecting device 920 is transmitted to a controller 910 in real time, and the controller 910 may adjust a diameter of the annular laser beam, a width of the annular laser beam, and an output of the laser beam based on the real-time temperature for each position of the substrate W.

The laser beam generator 500 may include the laser source unit 510, the beam shaper 520, and the beam expander 530. The laser source unit 510 outputs a laser beam from energy obtained from power. The beam shaper 520 converts a profile of the laser beam output from the laser source unit 510 into an annular shape and the beam expander 530 expands the laser beam to a parallel light type with a predetermined diameter to adjust a width of the beam forming the annular shape.

In the exemplary embodiment, the controller 910 may change the size or the distribution of the annular laser beam by a method of controlling to move a position of the moving module 750 in order to control the diameter of the annular laser beam, controlling a lens interval of the beam shaper 520 or the beam expander 530 in order to control the width of the annular laser beam, or changing an output of the laser source unit 510.

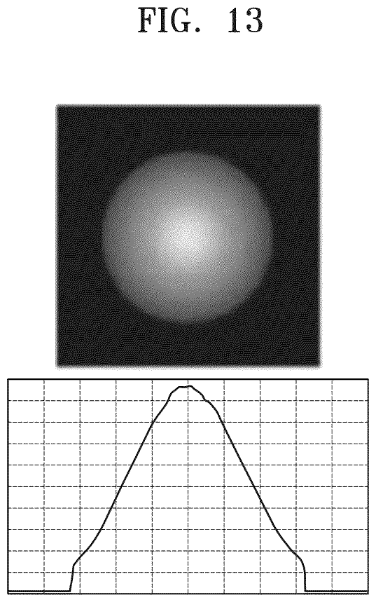

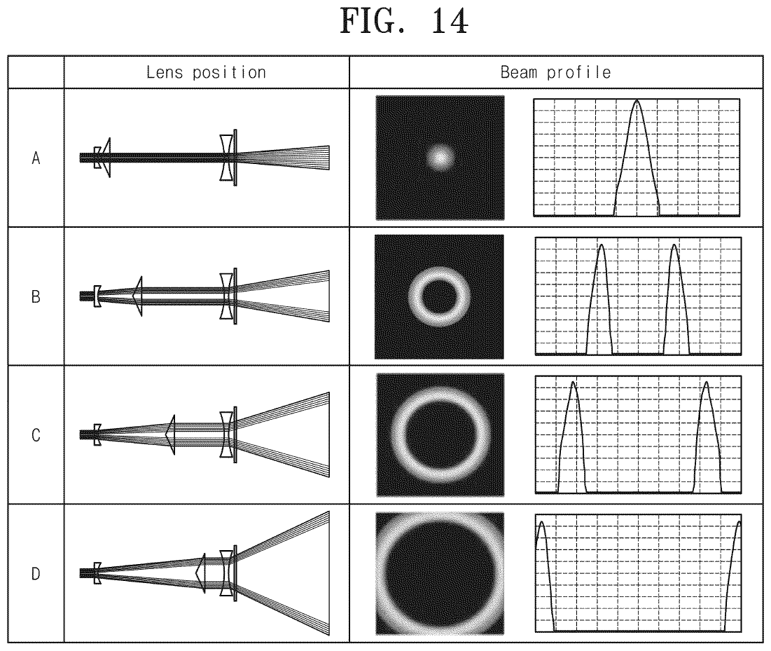

FIG. 13 is a diagram illustrating energy distribution of the laser beam incident on the annular beam emitting unit 700. The incident laser beam may be provided as a truncated Gaussian beam. FIG. 14 is a diagram representing a comparison of a diameter of the annular beam adjusted by the annular beam size adjusting module 710 when the laser beam of FIG. 13 is incident on the annular beam emitting unit 700. From row A to row D of FIG. 14, the second axicon lens 712 gradually moves away from the first axicon lens 711. In the exemplary embodiment, as the second axicon lens 712 constituting the annular beam size adjusting module 710 moves away from the first axicon lens 711, the diameter of the annular beam increases.

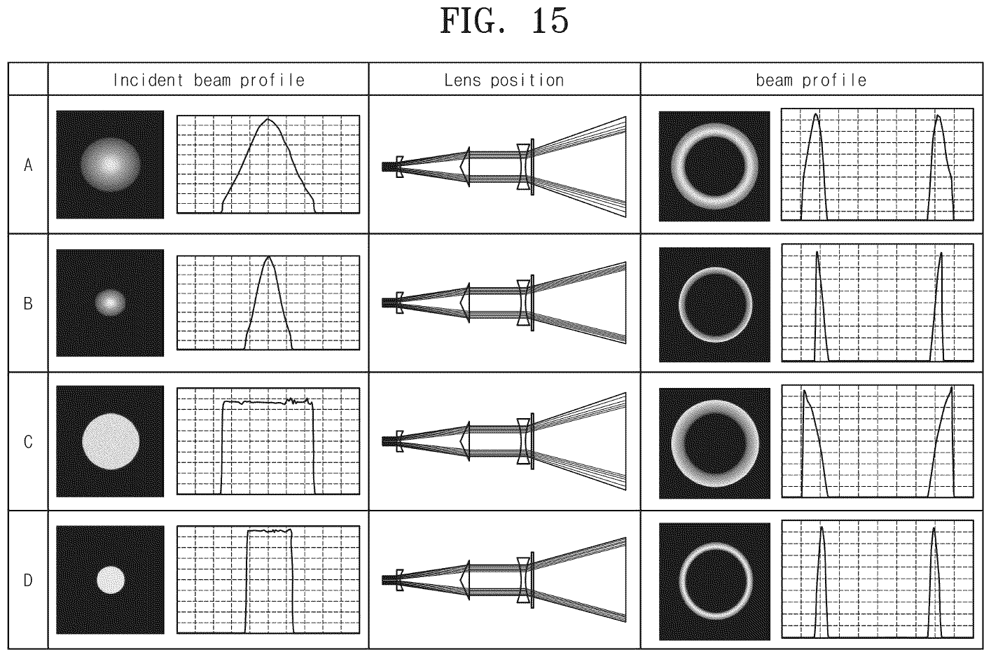

FIG. 15 is a diagram representing a comparison of beam profiles adjusted by the annular beam size adjusting module 710 according to a shape and a size of the laser beam incident on the annular beam emitting unit 700. Referring to FIG. 15, a case in which the size of a Gaussian beam is converted through the beam expander 530 and a case in which a laser beam is converted into a flat top beam through the beam shaper 520 are compared. A and B indicate that the size of the truncated Gaussian beam is changed through the beam expander 530, and C and D indicate that the size of the flat top beam is changed through the beam expander 530. As understood from the comparison of A and B and the comparison of C and D, when the beam is enlarged using the beam expander 530, the width of the annular laser beam is different, so that as the diameter of the incident laser beam is larger, the width of the laser beam is increased. Further, as understood from the comparison of A and C and the comparison of B and D, when the shape of the beam is different, the profile of the annular laser beam reaching the substrate is different. The temperature of each region of the substrate W may be more precisely controlled by adjusting the laser beam incident on the annular beam emitting unit 700 in consideration of these differences. Accordingly, it is possible to compensate for a decrease in temperature, which is a factor of a decrease in the etch rate ER for each region on the substrate W.

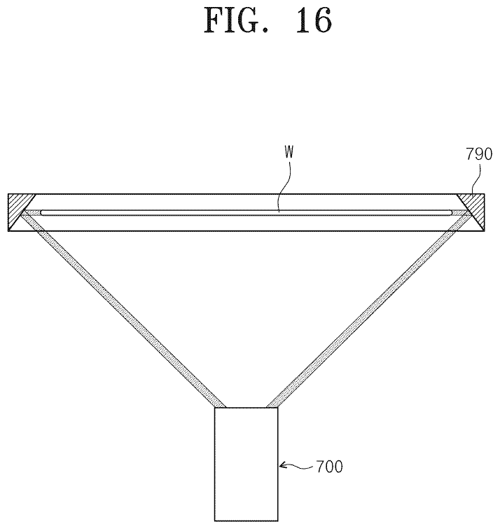

FIG. 16 is a diagram schematically illustrating a first application exemplary embodiment of the present invention. Referring to FIG. 16, the annular laser beam by the annular beam emitting unit 700 according to the exemplary embodiment of the present invention is set to have a larger diameter than the diameter of the substrate W, and a ring-shaped reflecting mirror 790 is disposed around the substrate W to reflect the annular laser beam, so that it is possible to directly heat the edge region of the substrate W.

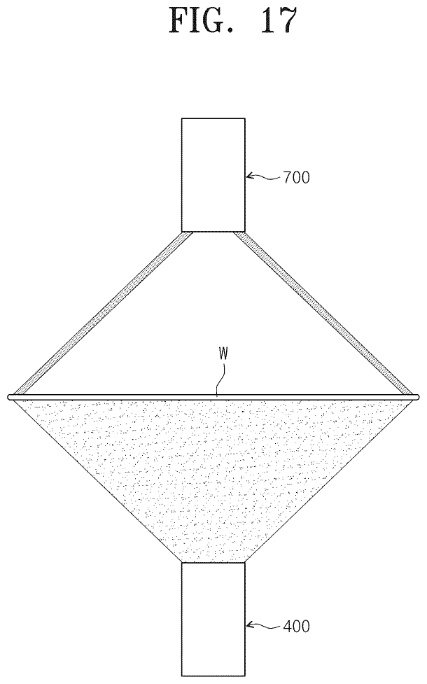

FIG. 17 is a diagram schematically illustrating a second application exemplary embodiment of the present invention. Referring to FIG. 17, a phosphoric acid puddle (not illustrated) may be formed on the upper surface of the substrate W, and the substrate W may be heated in an annular shape for each area by using the annular beam emitting unit 700 above the upper surface of the substrate W, and the front surface of the substrate may be heated by using the front beam emitting unit 400 in the lower surface of the substrate W.

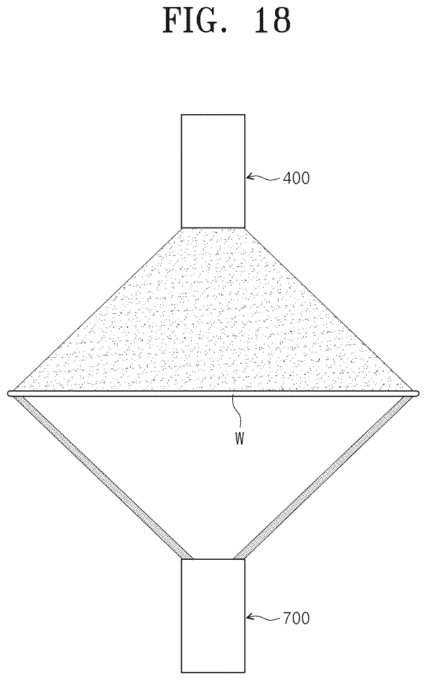

FIG. 18 is a diagram schematically illustrating a third application exemplary embodiment of the present invention. Referring to FIG. 18, a phosphoric acid puddle (not illustrated) may be formed on the upper surface of the substrate W, and the substrate W may be heated in an annular shape for each area by using the annular beam emitting unit 700 under the lower surface of the substrate W, and the front surface of the substrate may be heated by using the front beam emitting unit 400 above the upper surface of the substrate W.

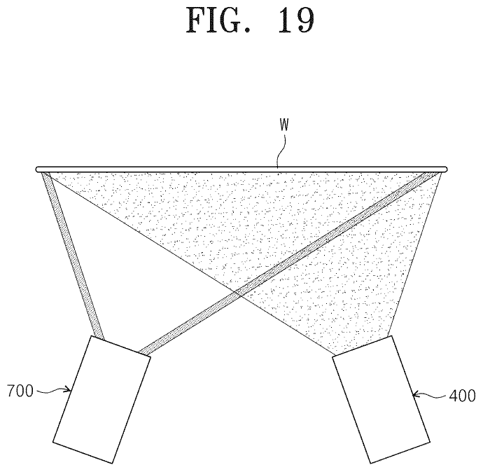

FIG. 19 is a diagram schematically illustrating a fourth application exemplary embodiment of the present invention. Referring to FIG. 19, a phosphoric acid puddle (not illustrated) may be formed on the upper surface of the substrate W, and the substrate W may be heated in an annular shape for each area by using the annular beam emitting unit 700 under the lower surface of the substrate W, and the front surface of the substrate may be heated by using the front beam emitting unit 400 under the lower surface of the substrate W. The annular beam emitting unit 700 and the front beam emitting unit 400 are disposed so that positions do not overlap, and the laser beam may be transmitted to the substrate W using an additional reflecting mirror.

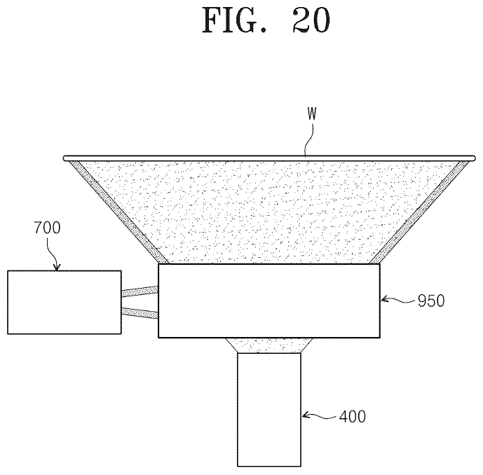

FIG. 20 is a diagram schematically illustrating a fifth application exemplary embodiment of the present invention. Referring to FIG. 20, a phosphoric acid puddle (not illustrated) may be formed on the upper surface of the substrate W, and the annular beam emitting unit 700 makes the annular laser beam be incident on an optical system 950 under the lower surface of the substrate W, and the optical system 950 transmits the annular laser beam to the substrate W to heat the substrate W in an annular shape for each area. Further, the front beam emitting unit 400 may make the front laser beam be incident on the optical system 950 under the lower surface of the substrate W, and the optical system 950 may transmit the front laser beam to the substrate W to heat the front surface of the substrate W.

According to the combination of the annular laser beam and the front laser beam described above with reference to FIGS. 17 to 20, in heating the front surface of the substrate W by using the laser beam, the temperature difference for each area of the substrate W may be compensated by using the annular laser beam, thereby achieving the uniform ER distribution for each area of the substrate W. Further, by tracking the temperature change of the substrate W according to the heating in real time, it is possible to uniformly improve the ER distribution according to the temperature change of the substrate W in response to the process variable.

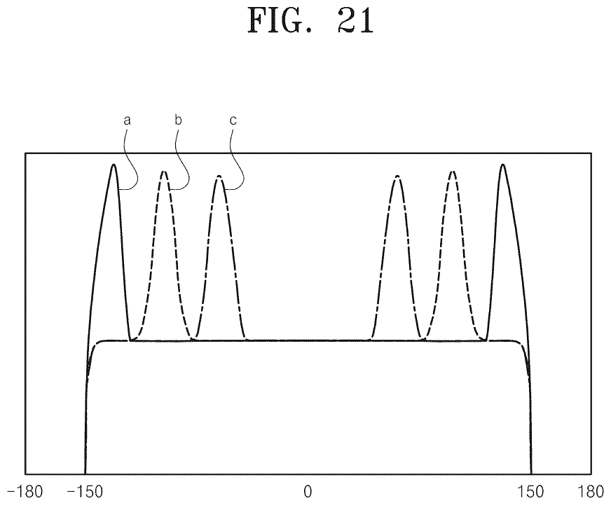

In the above, various exemplary embodiments of the present invention have been illustrated. However, there will be more various methods of combining the annular laser beam and the front laser beam, which are not described above, and the annular laser beam as used in the present invention is sufficient if the annular laser beam achieves the purpose of further heating a specific part by increasing the energy of the specific part in an annular shape than other regions, and as the combined beam in which the annular laser beam and another laser beam are combined is emitted to the substrate W, it should be construed that the increase of the energy intensity in the annular shape is included in the scope of the present invention. For example, this will be described with reference to FIG. 21. The Y-axis (vertical axis) represents the magnitude of the intensity, and the X-axis (horizontal axis) represents the position of the laser beam with respect to the 300 mm wafer. As illustrated in FIG. 21, the present invention may also achieve the technical object of the present invention by forming a combined beam in a shape in which the laser beams are combined so that a laser having the intensity for each area of graph a is changeable to a laser having the intensity for each area of graph b and also to laser having the intensity for each area of graph c.

The exemplary embodiment of the present invention may be modified to various application examples using the high-output annular laser beam for treating the substrate W, such as heating the substrate W. The process chamber may be a different chamber performing heating, not the chamber for cleaning or etching. For example, the process chamber may also be an annealing chamber.

Meanwhile, the configuration, storage, and management of the controller according to the above-described exemplary embodiments may be realized in the form of hardware, software, or a combination of hardware and software. The file data and/or the software configuring the controller may be stored in volatile or non-volatile storage devices, such as Read Only Memory (ROM); or memory, such as, for example, Random Access Memory (RAM), memory chips, devices, or integrated circuits, or a storage medium, such as Compact Disk (CD), Digital Versatile Disc (DVD), magnetic disk, or magnetic tape, which are optically or magnetically recordable and simultaneously machine (for example, computer)-readable.

1. A substrate treating facility, comprising:
a process chamber including an annular beam emitting unit which emits an annular laser beam to a substrate and heats the substrate; and
a laser beam generator configured to generate the laser beam emitted to the substrate through the annular beam emitting unit of the process chamber.

2. The substrate treating facility of claim 1, wherein the annular beam emitting unit includes:
an annular beam size adjusting module which is provided as one pair of lenses and adjusts a diameter of the annular laser beam; and
a beam expanding lens which is disposed in a downstream along an optical path of the annular laser beam to diffuse the annular laser beam to the substrate.

3. The substrate treating facility of claim 2, wherein the one pair of lenses constituting the annular beam size adjusting module is provided with axicon lens.

4. The substrate treating facility of claim 3, wherein the annular beam emitting unit further includes a moving module that enables any one of the pair of axicon lenses to relatively move with respect to the other, and
the adjustment of the diameter of the annular laser beam is achieved by adjusting a spaced distance between the one pair of axicon lenses.

5. The substrate treating facility of claim 1, wherein the laser beam generator includes:
a laser source unit which outputs a laser beam from energy obtained from external power;
a beam shaper which converts the laser beam output from the laser source unit into a truncated Gaussian beam or a flattop beam; and
a beam expander which enlarges the laser beam shaped by the beam shaper to a type of parallel light having a predetermined diameter.

6. The substrate treating facility of claim 1, wherein the process chamber further includes a front beam emitting unit which emits a front laser beam to a front surface of the substrate and heats the substrate.

7. The substrate treating facility of claim 1, wherein the annular beam emitting unit is optically connected with the laser beam generator by a laser beam transmitting member.

8. The substrate treating facility of claim 7, wherein the laser beam transmitting member is provided with optical fiber.

9. The substrate treating facility of claim 1, further comprising:
a controller,
wherein the process chamber further includes a heat detecting device which detects a temperature for each area of the substrate in real time, and
the annular beam emitting unit includes:
one pair of axicon lenses;
a moving module which adjusts a diameter of the annular laser beam by enabling any one of the pair of axicon lenses to relatively move with respect to the other and adjusting a spaced distance between the one pair of axicon lenses; and
a beam expanding lens which is disposed in a downstream along an optical path of the annular laser beam to diffuse the annular laser beam to the substrate, and
the laser beam generator includes:
a laser source unit which outputs a laser beam from energy from external power;
a beam shaper which converts the laser beam output from the laser source unit into a beam shape; and
a beam expander which enlarges the laser beam shaped by the beam shaper to a type of parallel light with a predetermined diameter, and
the controller feedback-controls one or more of a diameter of the annular laser beam by the movement of the moving module, an output of the laser source unit, the shape of the laser beam by the beam shaper, and a diameter of the laser beam shaped by the beam expander from real-time data detected by the heat detecting device.

10. The substrate treating facility of claim 1, wherein the process chamber further includes:
a substrate support unit which supports the substrate and rotates the substrate; and
a liquid supply unit including a chemical liquid discharge nozzle which discharges a chemical liquid to the substrate supported by the substrate support unit.

11. The substrate treating facility of claim 10, wherein the substrate support unit includes:
a window member which is made of a material allowing the laser beam emitted from the annular beam emitting unit to pass through and is provided under the substrate;
a chuck pin which supports a side portion of the substrate and makes the window member and the substrate be spaced apart from each other at a predetermined internal;
a spin housing which is coupled with the window member and is penetrated in a vertical direction to provide a path through which the laser beam is transmitted; and
a driving member which rotates the spin housing, and
the annular beam emitting unit is provided under the window member.

12. The substrate treating facility of claim 10, wherein the chemical liquid discharged from the liquid supply unit includes a liquid containing phosphoric acid.

13. The substrate treating facility of claim 10, further comprising:
a controller,
wherein the process chamber further includes:
a front beam emitting unit which emits a front laser beam to a front surface of the substrate to heat the substrate; and
a heat detecting device which detects a temperature for each area of the substrate in real time, and
the process chamber performs a first process of supplying the chemical liquid to the substrate, and a second process of heating the substrate with the front laser beam, and
the controller feedback-controls a profile of the annular laser beam from real-time data detected by the heat detecting device.

14. The substrate treating facility of claim 1, wherein the process chamber further includes a stage which moves up and down the annular beam emitting unit so that a distance between the annular beam emitting unit and the substrate is adjustable.

15. The substrate treating facility of claim 6, wherein the front beam emitting unit includes a lens module which includes one or more lens units, and processes the front laser beam to a shape corresponding to the substrate by refracting the front laser beam, and
an end of a laser beam transmitting member transmitting the front laser beam to the lens module and the lens unit are provided so that a distance therebetween is adjustable.

16. The substrate treating facility of claim 15, wherein the laser beam transmitting member is provided with optical fiber.

17.-19. (canceled)

20. A substrate treating facility, comprising:
a process chamber for liquid-treating a substrate in a single-wafer type;
a substrate support unit which is provided to the process chamber to support the substrate and rotate the substrate;
a liquid supply unit including a chemical liquid discharge nozzle which discharges a chemical liquid containing phosphoric acid to the substrate supported by the substrate support unit;
an annular beam emitting unit which is provided to the process chamber to emit an annular laser beam to the substrate and heat the substrate;
a front beam emitting unit configured to emit a front laser beam to a front surface of the substrate and heat the substrate;
a heat detecting device provided to the process chamber to detect a temperature for each area of the substrate in real time;
a laser beam generator configured to generate the laser beam emitted to the substrate through the annular beam emitting unit; and
a control unit,
wherein the annular beam emitting unit includes:
one pair of axicon lenses;
a moving module which adjusts a diameter of the annular laser beam by enabling any one of the pair of axicon lenses to relatively move with respect to the other and adjusting a spaced distance between the one pair of axicon lenses; and
a beam expanding lens which is disposed in a downstream along an optical path of the annular laser beam to diffuse the annular laser beam to the substrate, and
the laser beam generator includes:
a laser source unit which outputs a laser beam from energy from external power;
a beam shaper which converts the laser beam output from the laser source unit into a beam shape; and
a beam expander which enlarges the laser beam shaped by the beam shaper to a type of parallel light with a predetermined diameter, and
the controller feedback-controls one or more of the diameter of the annular laser beam by the movement of the moving module, an output of the laser source unit, the shape of the laser beam by the beam shaper, and a diameter of the laser beam shaped by the beam expander from real-time data detected by the heat detecting device.
